(19) United States
(12) Patent Application Publication
(10) Pub. No.: US 2024/0215212 A1
(43) Pub. Date: Jun. 27, 2024

(54) Retrofittable Multifunctional Display Module

(71) Applicant: Ralph PECHMANN, Cottbus (DE)

(72) Inventor: Ralph PECHMANN, Cottbus (DE)

(21) Appl. No.: 18/288,050

(22) PCT Filed: Apr. 4, 2023
(86) PCT No.: PCT/DE2023/100257

§ 371 Date: Oct. 24, 2023

(30) Foreign Application Priority Data
Apr. 6, 2022 (DE) 10 2022 108 229.6

(51) Int. Cl. H05K 7/20

(52) U.S. Cl. CPC H05K 7/20972; H05K 7/20145; H05K 7/20172

(57) ABSTRACT

Summary

Retrofittable multifunctional display module, designed for retrofitting in doors, walls, cabinets, and its method for temperature control, characterized in that the internal temperature of the display module in the closed state is detected via the temperature sensors 7 and subsequently the fans are controlled as a function of the internal temperature of the display module and, depending on the internal temperature of the display module, modules are switched off and, in an overtemperature range of the internal temperature of the display module, the appliance is switched off completely.

The invention relates to a retrofittable multifunctional display module for all retrofitting of doors, walls, cabinets, and other straight surfaces, which are to be extended with this product.

US 2015/0250067 is known from the prior art.

A display housing assembly includes a cabinet enclosing an interior space, the cabinet including a front wall and a rear wall, one or more display modules at least partially enclosed within the interior space, one or more display modules adapted to form an electronic display on the front wall, one or more fans mounted on the rear wall, each of the one or more fans comprising a fan inlet directed rearward from the rear wall and a fan outlet directed into the interior, a vent extending at least partially between the front wall and the rear wall, the vent providing a first path for cooling air to pass from a front side of the housing to the array side of the housing and an outlet providing a second path for heated air to exit the interior.

The displays can be mounted on the front or and rear wall of the cabinets.

Furthermore, US 2016/0192536 is known.

An electronic display arrangement for suspending an electronic display from one or more elongated rods is disclosed. A closed loop of circulating fluid, such as air, may be provided in a sealed electronics compartment. An open loop channel may allow fluids, such as ambient air, to flow through the assembly via a channel defined by the space between the rear tray and the electronic display. A pair of passageways preferably extend vertically along the assembly and are configured to accommodate the passage of an elongated element. Clamps may be used within these passageways to secure the assembly to the elongated elements.

The object of the invention is to develop a retrofittable multifunctional display module which, due to its low weight and an internal self-sufficient structure, can be retrofitted anywhere apart from the mains supply.

The object of the invention is solved by developing a retrofittable multifunctional display module according to claim 1 and the following description.

Retrofittable multifunctional display module, which can be retrofitting in doors, walls, cabinets, and its method for temperature control, whereby via the temperature sensors 7, the internal temperature of the display module is detected in the closed state via the temperature sensors 7 and subsequently temperature of the display module is detected via the temperature sensors 7 and the fans are controlled and, depending on the internal temperature of the display module are switched off and, in a Overtemperature range of the internal temperature of the display module the device is switched off completely.

Arrangement of the multifunctional display module for guiding the air flow within the display module, wherein radial fans 14 are given below, and subsequently the air flow 25 is divided via a chassis 20, which is arranged centrally in the display module, and is recombined above the display module by an air baffle 26, which is fastened inwardly aligned to the rear wall 18 in the upper third below, and exits through the air outlet openings 6.

The retrofittable multifunctional display module, hereinafter referred to as the display module, has been designed in such a way that, due to its low weight and its own ventilation, it is a self-sufficient application, apart from the supply of the mains voltage. For changes to the AD content, it is also necessary to provide the display module with an Internet connection. This can be wired (LAN), via LTE or WLAN. When installing or retrofitting the display module, it is therefore possible to run all multimedia activities on the display, e.g. advertising, films, images, content directly from the Internet, information.

An important prerequisite for the use of the display module is that the static safety in the installation location is given, but this is not a problem in most cases due to the low weight of the inventive solution.

The display module can therefore be used wherever a separate power supply is available to power the display module or where it can also be used from a ventilation point of view. In particular, the display module is for door installation in cabinets, in cabinet walls of cabinets or also for walls that are accessible from the rear.

The key aspect of the invention is that a concept has been developed by which the application of the display module for multifunctional casings known per se has been implemented, whereby the installation takes place in the respective door of the multifunctional housing.

The multifunctional housing is a double-walled SiCab outer cabinet and offers optimal installation and climatic conditions for electronic assemblies, protecting them from the effects of weather and virtually eliminating damage.

The modular housing consists of an aluminum profile frame, inner housing, and an attached plastic outer shell made of polycarbonate.

Active climate control components can be installed in the roof module.

The inventive product is an outdoor-capable, retrofittable, multifunctional display module which is designed for installation in multifunctional cabinets of the SiCab 8, 12, 15, 18 and 24 type. Installation in other housings, walls, cabinets, and doors is also possible.

Various contents can be displayed on it in 16:9 portrait format. It does not matter whether it is fixed images or moving videos, combined content of image and video or online content directly from the Internet.

The image content is generated by an integrated player and transmitted to the LCD panel.

The content is received and managed on the player by means of CMS software that can work with different operating systems. The software is controlled via WLAN, mobile radio, LAN, or USB. This enables location-independent access to the content and hardware. In the event of a network failure, the most recently imported content continues to run until the network (Internet) is restored. This ensures that there is no loss of content. To achieve this, the content is temporarily stored locally in the display module.

The display itself and all components are housed in a powder-coated aluminum frame.

These are protected against vandalism and solar radiation by a laminated safety glass (LSG) front pane that is firmly bonded to the frame. The front pane is chemically non-reflective and consists of two layers of float glass bonded together using laminated safety glass-S Solar-Protect film.

A brightness sensor on the lower side of the frame determines the ambient brightness and regulates the display intensity. This ensures that there is no glare or disturbance in public spaces due to excessive brightness, even at night. The choice of the lower side greatly reduces the risk of soiling, tampering or vandalism and thereby increases operational safety.

The display is supplied with AC or DC power (depending on requirements), which is provided by a connector in the multifunctional housing. The AC voltage can range from 100 to 230 volts and the DC voltage from 24 volts.

The display is designed for continuous operation and has its own active cooling system by means of several radial fans in the lower part of the housing. This ensures the intake of cool air from the near-ground area as well as a very high air throughput for cooling the components. Due to this cooling concept and the choice of the installation location of the display module, the modules of the cabinet behind it are not negatively affected. The display module is installed outside the IP range of the multifunctional housing. This means that the climate inside the cabinet is not affected. This was also proven in the climate chamber test.

Due to the use and conceptual design of radial fans, the air flow is very efficient. Air baffles inside the cabinet allow the air flow to be directed specifically to the areas to be cooled. This unique selling proposition has been developed through many computer simulations and has been repeatedly refined and adapted. A test in the climate chamber of an independent laboratory then confirmed the simulations. FIG. 7 illustrates the air flow in the lateral cross-section of the display module.

The display has gone through various stages of development and testing during its development. The design was adjusted after each test and then tested again. It meets all the criteria of operational safety in the outdoor environment, especially for public roads, paths, and squares.

To create an optimal interior temperature, the air flow conditions were adjusted several times.

This was achieved by closing air bypasses and incorrectly positioned air slots in the display module, as well as changing the fan design and inserting air baffles. By arranging the fans in the lower area, cool air can be drawn in from the near-ground area and is then directed upwards through the system to the surfaces requiring cooling.

Another important factor was a reduction and change in the position/location of assemblies. The airflow is obstructed as little as possible by a more open design of the individual modules. Furthermore, cable routes were optimized to achieve the lowest possible air resistance. Where possible, the cable routes are laid longitudinally in the direction of the airflow.

The fan control is performed in several stages. It is used for optimal cooling of the system and reduction of fan noise. By reducing fan noise, it is now possible to place the display in quiet areas in public spaces. The fans are regulated in several stages by temperature sensors located at critical points. According to the computer simulation, the heat hotspot is in the upper area of the display module. This is also where these sensors are located.

### Fan Control is in Five Stages:

### Stage 1 (<40° C./<104° F.):

2 of the 4 fans operate at half speed.
This reduces the noise level to a minimum at low temperatures, ensures cooling of the active components, provides for permanent air circulation, and thus prevents condensation from forming at low temperatures.

### Stage 2 (40° C./104° F.):

4 of the 4 fans operate at half speed.
As the temperature rises, we increase the airflow and sufficient cooling can be ensured. By continuing to reduce the speed, the noise level is reduced to a minimum.

### Stage 3 (50° C./122° F.):

If the temperature continues to rise, both pairs of fans are increased to full speed.

### Stage 4 (54° C./129.2° F.):

If the temperature continues to rise, the main consumer is switched off electronically. The main consumer is the LED backlight with approx. 100-120 watts.
Because of the lower power consumption due to the shutdown and thus lower heat emission, the system can cool down.
During this shutdown, both pairs of fans run at full speed, providing maximum airflow.
When the temperature has dropped by approx. 5° C./41° F., the main consumer is switched on again.
During the time the main consumer is switched off, all other assemblies continue to run normally.
This reduces downtime for content playback but protects the system from excessive temperatures.

### Stage 5 (>60° C./>140° F.):

If the temperature rises outside the specification, the system is switched off in an emergency.
The emergency shutdown disconnects all components from the power supply. The components are without power during this time.
If the temperature falls back within the specification, the system switches on again automatically.
A reboot then takes place, and the CMS starts automatically. The network connection is re-established.
All content is displayed normally again.

The entire technology of the network operator as well as the mechanics of the cabinet itself are not negatively affected by the display. This has been proven by testing on the computer and in the climatic chamber, as well as resistance verification by an independent testing laboratory.

The device is protected against rain, intense sunlight, and vandalism.

Various protective measures ensure that the device is safe to touch and not hazardous to passers-by and service personnel.

The invention will now be explained in more detail using a design example with figures.

### The Figures are

FIG. 1, Interior view of the functional elements of the display module,

FIG. 2, Block diagram,

FIG. 3, Installation type of the display module,

FIG. 4, Front view,

FIG. 5, Rear view, and illustration of the air flow through the entire display module,

FIG. 6, Rear view showing the air baffles,

FIG. 7, Lateral view showing the air flow and the internal air baffles.

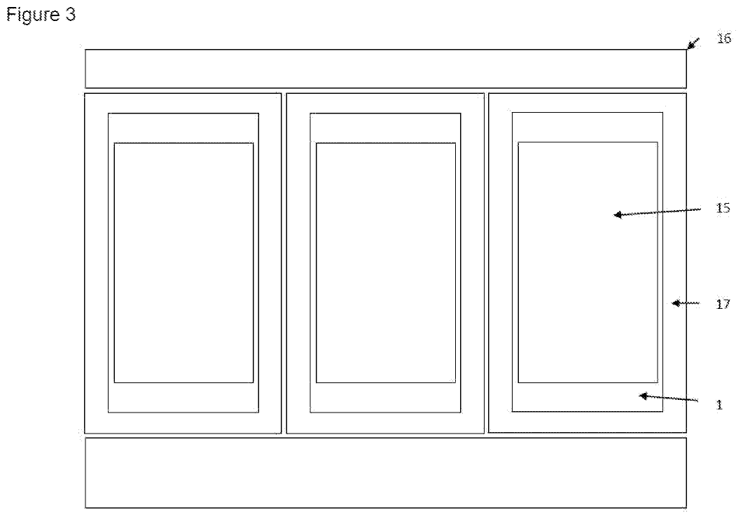

FIG. 3 illustrates an installation type of the display module, in which a multifunctional housing 16 is provided with three doors 17 as an example.

The laminated safety glass panel 15 with the LCD panel 5 behind it is inserted into the frame 1 of the door 17.

The display is installed in a standard door of the multifunctional housing 16.

Standard doors 17 with dimensions of 100 cm, 70 cm and 60 cm are used. The frame is inserted centrally in the door, firmly connected and sealed.

The multifunctional housing 16, the doors 17 and the frame 1 of the display module, are RAL color 7038.

### Conformity and Safety

Protection class IP: IP55 (used and fitted as intended in the multifunctional housing and in the closed state) DIN EN 60529 (VDE0470-1) DIN EN60529 Test Report P50-22-0265 dated 14.-18.07.2022
Protection class electrical: Protection class 1 DIN EN 61140 (VDE 0140-1)
Pane: Laminated safety glass front pane 2×2 mm with laminated safety glass-S foil (laminated safety glass with UV and IR filter as well as chemical antiglare coating) Laminated safety glass according to DIN EN 12543—Ball impact resistant according to DIN 18032-3—Impact resistant according to DIN EN 50102
Temperature: automatic temperature monitoring
Resistance against manual break-in attempts: Test report 2622015-02 dated 04.03.022, resistance class RC2. Tested by EPH, 01217 Dresden, Germany
Climatic test: DIN EN60068-2-5 Test Report P50-22-0206 dated 23 Jun. 2022
Shock test: DIN EN 60068-2-27 (Issue 2010-02) Test Report P50-22-0286 dated 12 Aug. 2022
Salt spray test: DIN EN 60068-2-11 (Issue 2000-02) Test Report P50-22-0286 dated 12 Aug. 2023
Cold test: DIN EN 60068-2-1 (Issue 2008-01) Test Report P50-22-0286 dated 12 Aug. 2022
Electromagnetic compatibility test (Class B): as per Test Report PB EMV 140223-1 and PB EMV 070323-1 DELTA IDL GmbH 4474 dated 14 Feb. 2023
Device safety: DIN EN IEC 62368-1:2020+A11:2020 Test Report PB_GS_2023-03-01_PA4475 2011/65/EU RoHS 2014/53/EU RED

### Technical Data:

### Outdoor Display Module

### Housing

Front: aluminum sheet, powder-coated (RAL7038), outdoor-ready, corrosion class C3.
Panel cover+filter holder: aluminum sheet, powder-coated (RAL7038), outdoor-ready

Laminated safety glass front pane 2×2 mm chemically coated antiglare float glass with VSG-S film Solar Protect film bonded between the panes (infrared absorbing and reflecting), fan (air intake and air discharge via control box housing)

### Display

Diagonal: 32″
Resolution: 1920×1080
Aspect ratio: 16:9
Brightness: 2000-3000 cd/m2
Contrast ratio: 1200:1
Color support: 8 Bit (16,7M)
Response time: 9 ms
Viewing Angle: 178°/178°
Operating time: 24/7
Orientation: Portrait
Lifetime: 50.000 h

### Brightness Control Via Ambient Light Sensor

### Player

### Various Models Depending on Customer and Application

### Dimensions and Weight Housing

Dimensions: W×H×D=ca. 487 mm×887 mm×67 mm
Weight: ca. 15 kg

### Connection Data

Connection data: 100-240V/50 Hz/60 Hz variant supply with AC voltage
Power consumption: ca. 140 W

### Ambient Conditions

Protection class: IP55
Temperature: −20° C. to +40° C. (−4° F. to 104° F.)
Humidity: 0% to 95%

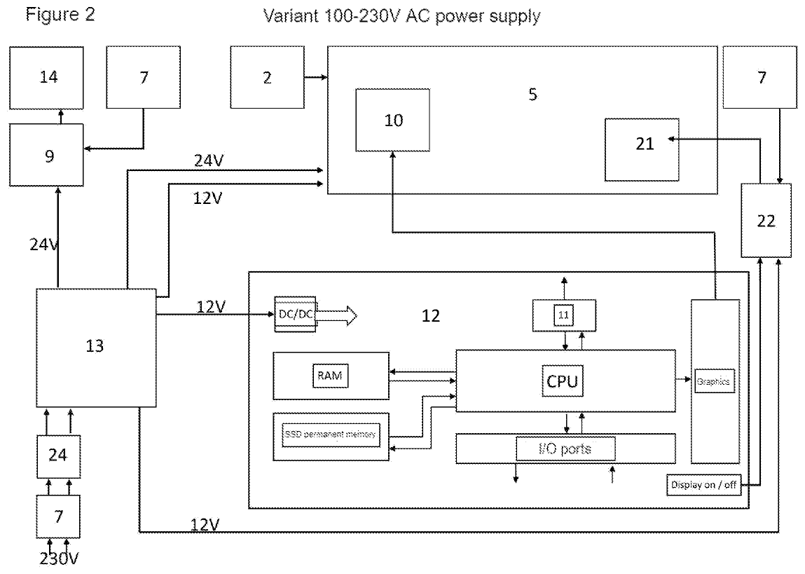

Electrical description for 100 VAC-230 VAC version is shown in FIG. 2 Block diagram.

In the version supply with DC voltage/DC current, the power supplies are so-called DC/DC converters, but also with the function of converting the input voltage into the required output voltages.

### Power Supply Unit 13:

The power supply unit 13 is supplied with 100-240V AC (alternating current). The task of the power supply unit 13 is to supply all components of the entire system with a stabilized DC voltage. +12V and +24V are provided. Furthermore, the power supply unit 13 is protected against excess current and short circuit by internal protection circuits.

The operating temperature range is 0° C. to 50° C. (32° F. to 122° F.). The ambient air humidity may range between 30% to 85%.

### LCD Unit:

The components of the LCD unit include the LCD panel 5 with integrated LED-based backlighting, the T-Con module 10, LED controller 21 and ambient brightness sensor 2.

The image signals are fed to the T-Con module 10 via the “LVDS” standard (51 pin, 2 channel, 8 bit). This module then provides the digital signals for the control matrix of the LCD. The T-Con module 10 works with +12V.

To control and regulate the LEDs, there is an LED controller 21 on the display. This is supplied with +24V. Its task is to provide the currents for the LEDs and to realize a brightness control corresponding to the ambient brightness.

The brightness control range in dimming mode is 30% to 100%. A control voltage coming from the player/computer can switch the back light on or off (0V=off, >2.5V=on type 3.3V).

The maximum working temperature of the LCD unit is +50° C./122° F. on the back side and +68° C./154.4° F. on the front side. The ambient air humidity may range between 30% and 85%.

### Player/Computer 12:

An industrial computer circuit board is used here. It is equipped with CPU, RAM, and SSD fixed memory. Various operating systems can be installed on this board, such as Windows, Linux, etc. The image signals output can be via HDMI or LVDS. Various options are available for I/O ports.

An additional LTE or WLAN module 11 with a remote and externally routed antenna can be installed directly as an add-on module on the player/computer 12. The LTE module also has a remote and outward-facing antenna that is mounted in place of the WLAN antenna 3.

The working basis is an operating system with integrated driver software for the hardware and CMS software for managing the AD content and controlling the hardware.

Depending on the CMS software (Content Management Systems) used, the end customer now has various options for operation. The content is supplied and managed via wireless (WLAN, mobile communications) or via cable (LAN, USB). Even if the connection to the CMS server is interrupted, the content will not be lost because it is stored locally. Direct operation on the unit is not provided but can be built in at the customer's request.

The supply voltage of the player/computer can range between +9V and +36V.

The operating temperature for this board is between 0° C. and +60° C. (32° F. to 140° F.).

The ambient air humidity can range from 10% to 90%.

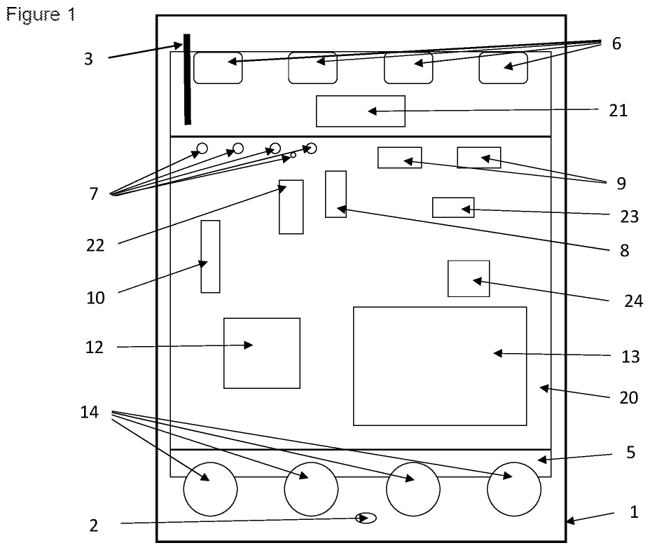

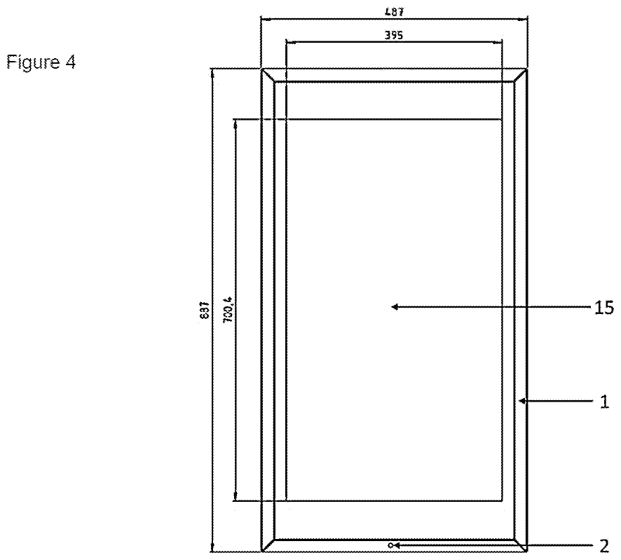

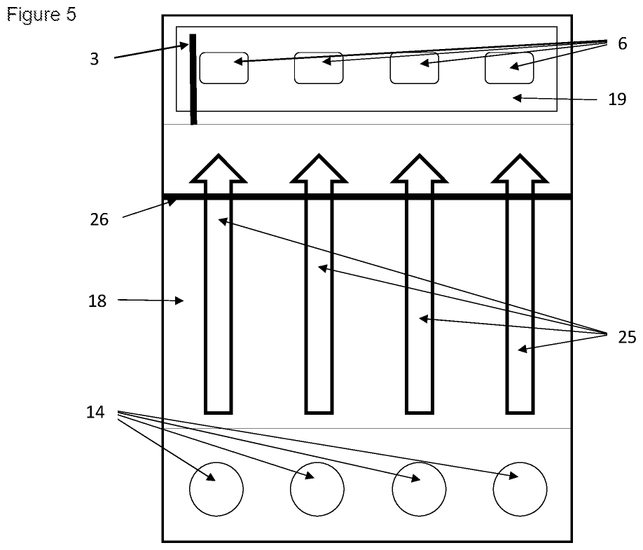

FIG. 1 illustrates the structure of the individual functional elements of the display module. Here, it is also important to look at FIG. 4, which shows the front view of the display module in the frame 1 with the laminated safety glass pane 15 and the LCD panel 5 behind it. The rear wall 18 in FIGS. 5, 6 and 7 specifically illustrates the inventive solution in the arrangement of the ventilation system, which makes a significant contribution to the functional design of the display module in terms of ventilation.

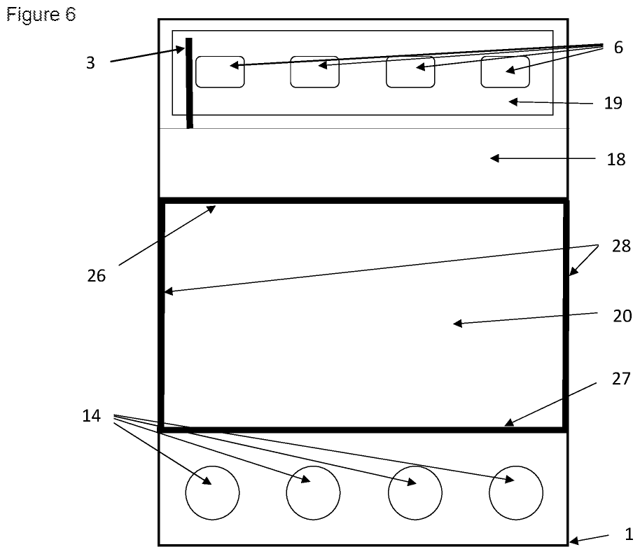

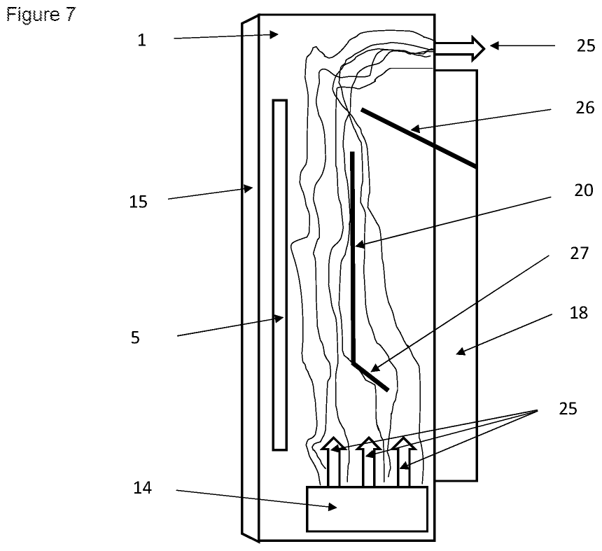

FIGS. 5 and 7 show the air flow and the installation position of the fans. FIGS. 6 and 7 show the air baffles 26, 27, 28.

FIG. 4 shows the dimensions of the display module of 487×887 mm and the laminated safety glass panel 15 with the LCD panel 5 behind it measuring 395×700.4 mm.

FIG. 1 shows the interior view of the display module and its functional elements.

Specifically, the display module consists of a frame 1, which has an ambient brightness sensor 2 underneath facing towards the front. Furthermore, the four radial fans 14 are located underneath. The LCD panel 5 is attached above.

The individual components such as fan control 9, power connection/distributor 24V 8, power connection/distributor supply voltage 23, temperature switch 22, mains input filter for supply with 100-230V AC voltage 24, player/computer circuit board 12, T-Con module 10 and power supply unit/power supply 13 are integrated on the chassis 20.

Five temperature sensors 7 are provided in the upper area of the chassis 20. The temperature sensors 7 are used to monitor the internal temperature of the display module and to regulate the intensity of the ventilation and control it in such a way that module shutdowns are triggered, and the device is completely disconnected from the supply voltage in the event of overheating.

Furthermore, above the chassis there is an LED controller 21 as part of the LCD panel 5, the antenna for WLAN or LTE 3 and the air outlet openings 6.

It is important to mention that the radial fan 14, the air outlet openings 6 and the WLAN or LTE antenna 3 are only present in the rear wall 18 of the display module.

The rear wall 18 of the display module is shown again in FIG. 5. FIG. 5 illustrates the rear wall 18 of the display module, whereby four radial fans 14 are installed in the lower area of the rear wall 18 and four air outlet openings 6 are provided in the upper area. In addition, the WLAN or LTE antenna 3 is provided near the air outlet openings 6.

It is also important to mention that an air baffle 26 is present on the rear wall 18, approximately at the lower end of the upper third of the display module. This air baffle 26 is arranged at an angle to the interior of the display module and is permanently connected to the rear wall 18. This is an air baffle that is approximately 5 cm across the full width of the rear wall 18 and is oriented at an angle of 45 degrees to the interior of the display module. Furthermore, the airflow 25 from the radial fans 14 towards the air outlet openings 6 is illustrated.

FIGS. 6 and 7, which specifically show the airflow and the problem of the air baffles 26, the angled lower chassis 27 and the side panels chassis 28, are given below.

FIG. 6 shows the rear wall 18. The chassis 20, which is not attached to the rear wall 18, is shown in the center. The chassis 20 has a bend at the lower chassis 27, which is approx. 2 cm in size and is arranged at an angle of 45 degrees to the rear wall 18. Furthermore, there is the air baffle 26, which is arranged on the rear wall as described above towards the inner area of the display module.

It is important to note that two side plates 28 are arranged on the chassis 20, which prevent the airflow 25 from bypassing the chassis 20 laterally, but instead guiding it above and below the chassis as shown in FIG. 7.

In particular, FIG. 7 shows the airflow 25 from the radial fans 14 to the air outlets 6. The arrangement of the chassis 20 with its angled lower chassis 27 is illustrated here. The position of the air baffle 26 on the rear wall 18 is also shown. The lower chassis 27 is angled at 45 degrees. This divides the airflow in the lower area inside the display module, whereby it is important that the airflow is guided more strongly below the chassis 20 due to the angle of the lower chassis 27. The air baffle 26 with an angle of approx. 45 degrees is firmly connected to the rear wall 18 and has a size of approx. 5 cm over the full width of the rear wall and brings the air flow 25 together again in the upper area of the display module and guides it towards the air outlet openings 6.

In the lower area there are four radial fans 14, which provide the inventive air flow.

Four radial fans 14 were installed to ensure good and sufficient ventilation. The airflow is guided over integrated baffles 26, 27 and thus bypassed at the important points. The side plates 28 also prevent the air from flowing sideways.

The cold air is fed in at the lower edge of the display unit by means of the four radial fans 14 and is directed upwards, over the areas to be cooled, to the air outlet openings 6.

To reduce the sound level caused by the fan noise, the radial fans 14 are regulated and switched. The speed is reduced via DC/DC converters which generate approx. +15V from +24V and thus supply the radial fans 14 (radial fans rotate at approx. 50%). At indoor temperatures below 40° C. (104° F.), one pair of fans is out of operation and the other pair of fans rotates at approx. 50%. If the temperature rises above 40° C. (104° F.), a bimetal closes and supplies the second pair of fans with voltage via a DCDC converter. Here, too, both pairs still rotate at approx. 50%. From a temperature of 50° C. (122° F.), the voltage reduction is bypassed and both pairs rotate at 100%. From 54° C. (129.2° F.), the LED backlighting is switched off, which is approx. 100 W to 120 W, thus reducing the heat generation and the unit cools down again. Both pairs of fans rotate at 100% at this point.

### Additional Thermal Protection Measures

Since higher ambient temperatures can occur due to weather conditions and location, an overtemperature protection using bimetal is built in, which interrupts the power supply from an upper temperature limit of 60° C. (140° F.) at the display, thus preventing the system from overheating.

The screen surface is protected by a Solar Protect film integrated in the laminated safety glass pane, which is infrared-absorbing and reflective.

### Advantages of the Invention

The display module was developed to be integrated into existing multifunctional housings.

Since these housings can be found in every city and almost every street, the display module is based on a large existing infrastructure. This eliminates the need for expensive and time-consuming construction work. Moreover, due to the large number of these housings, a wide audience can be targeted.

Another special feature is that this display can not only be used for advertising purposes but can also show warning and evacuation plans in emergency and disaster situations. Events, interesting facts about the area and tourist information can also be transmitted and displayed in real time.

The low weight of approx. 15 kg as well as the highly efficient ventilation concept for the display module are unique in the outdoor sector.

Another unique selling point is that the sound emission caused by fan noise is reduced to a minimum. This means that our display module can also be used in, for example, residential areas.

### REFERENCE

1 Frame
2 Ambient brightness sensor
3 WLAN or LTE antenna
4
5 LCD panel
6 Air outlet openings
7 Temperature sensors
8 Power connection/distributor 24V
9 Fan control
10 T-Con module/part of the LCD-Panel
11 WLAN/LTE module optional on PC (mainboard)
12 Player/computer circuit board
13 Power supply unit/power supply
14 Radial fans
15 Laminated safety glass pane and LCD panel behind (5)
16 Multifunctional housing
17 Door
18 Rear wall
19 Removable frame
20 Chassis
21 LED controller/part of the LCD panel
22 Temperature switch
23 Power connection/distributor supply voltage
24 Mains input filter for supply with 100-230V
25 Air flow
26 Air baffle rear wall
27 Lower chassis angle
28 Chassis side plates for guiding air flow

1.-2. (canceled)

3. An arrangement for cooling a retrofittable multifunctional display module,
wherein the retrofittable multifunctional display module is designed for retrofitting in doors, walls, cabinets,
wherein active cooling is provided in an interior of the display module via fans towards an air outlet opening,
wherein the fans are installed at a bottom of the display module,
wherein an air flow leads to the air outlet opening above the display module,
wherein the air flow is directed over a chassis on both sides,
wherein the chassis is arranged centrally and not connected to a rear wall,
wherein there is a flat projection below the chassis of a lower chassis at an angle towards the rear wall, and
wherein side plates are provided on the chassis,
wherein the side plates guide the air flow over the chassis on both sides,
wherein an air baffle is provided above an inner display module, and
wherein the air baffle is oriented inwards and is attached to the rear wall.
